(19) United States
(12) Patent Application Publication
(10) Pub. No.: US 2025/0114812 A1
(43) Pub. Date: Apr. 10, 2025

(54) SUBSTRATE PROCESSING APPARATUS

(71) Applicant: SCREEN Holdings Co., Ltd., Kyoto (JP)

(72) Inventors: Akira ITO, Kyoto (JP); Yasuhiko NAGAI, Kyoto (JP); Takashi AKIYAMA, Kyoto (JP); Shigeru YAMAMOTO, Kyoto (JP); Keiji IWATA, Kyoto (JP); Kenji EDAMITSU, Kyoto (JP)

(21) Appl. No.: 18/906,149

(22) Filed: Oct. 3, 2024

(30) Foreign Application Priority Data
Oct. 6, 2023 (JP) 2023-174193

(51) Int. Cl. B05B 13/02; B05B 12/02

(52) U.S. Cl. CPC B05B 13/0221; B05B 12/02; B05B 13/0292

(57) ABSTRACT

A substrate processing apparatus includes: a plurality of first mist nozzles provided inside a chamber and arranged at a predetermined second interval along an arrangement of a plurality of substrates; and a plurality of second mist nozzles provided inside the chamber and arranged at the second interval along the arrangement of the plurality of substrates. The first mist nozzles are disposed on opposite sides of the second mist nozzles, with respect to the substrates in plan view. The first and second mist nozzles are disposed in a manner facing the substrates in plan view. The first mist nozzles are arranged in a manner offset from the respective second mist nozzles by a length corresponding to a half the second interval in the direction of the arrangement of the substrates W. Each of the first and second mist nozzles sprays the liquid as at least one of mist and droplets.

### CROSS-REFERENCE TO RELATED APPLICATIONS

This application claims priority to Japanese Patent Application No. 2023-174193 filed Oct. 6, 2023, the subject matter of which is incorporated herein by reference in entirety.

### BACKGROUND

### Technical Field

The present invention relates to a substrate processing apparatus for processing substrates. Examples of such a substrate include a semiconductor substrate, a substrate for a flat panel display (FPD), a glass substrate for a photomask, a substrate for an optical disk, a substrate for a magnetic disk, a ceramic substrate, and a substrate for a solar cell. Examples of the FPD include a liquid crystal display device and an organic electroluminescence (EL) display device.

### Related Art

A conventional substrate processing apparatus includes a chamber for housing substrates, a processing tank installed inside the chamber, and a holder for holding the substrates (see, for example, Japanese Patent Application Laid-Open No. 2023-020268). A water repellent discharger, a first solvent discharger, and a second solvent discharger are installed in the chamber.

The water repellent discharger discharges water repellent vapor. The first solvent discharger discharges isopropyl alcohol (IPA) vapor. The second solvent discharger discharges a mixed gas containing IPA and nitrogen gas. The second solvent discharger has a plurality of (e.g., twenty) two-fluid nozzles. The plurality of two-fluid nozzles are arranged in two rows.

### SUMMARY

Solvent adheres to a substrate better when the solvent is supplied as mist (solvent mist), rather than as solvent vapor. However, merely by discharging the solvent mist, the solvent may be consumed wastefully. For example, if a plurality of substrates are mainly subjected to an atmosphere of a solvent mist so as to allow the solvent to adhere to the substrates, the solvent may be consumed wastefully because a large amount of the solvent adhere to members other than the plurality of substrates (e.g., a processing tank and a lifter), and only to some of the substrates. Therefore, it might not be possible to apply the solvent efficiently to the substrates.

The present invention has been made in view of the situation described above, and an object of the present invention to provide a substrate processing apparatus capable of efficiently applying a liquid to substrates.

In order to achieve such an object, the present invention uses the following configurations. That is, a substrate processing apparatus according to the present invention is a substrate processing apparatus for processing a plurality of substrates, the processing apparatus including: a chamber configured to house a plurality of substrates in a vertical orientation, in a manner arranged linearly at a preset first interval in a horizontal direction; a substrate holder provided inside the chamber and configured to hold the plurality of substrates; a plurality of first nozzles provided inside the chamber and arranged at a predetermined second interval along an arrangement of the plurality of substrates; a plurality of second nozzles provided inside the chamber and arranged at the second interval, along the arrangement of the plurality of substrates, in which the plurality of first nozzles are disposed on opposite sides of the plurality of second nozzles with respect to the plurality of substrates in plan view; the plurality of first nozzles and the plurality of second nozzles are disposed in a manner facing the plurality of substrates in plan view; the plurality of first nozzles are arranged in a manner offset from the plurality of respective second nozzles by a length corresponding to a half the second interval in a direction in which the plurality of substrates are arranged; and each of the plurality of first nozzles and the plurality of second nozzles is configured to spray a liquid as at least one of mist and droplets.

With the substrate processing apparatus according to the present invention, mainly a liquid containing at least one of mist and droplets sprayed from the first nozzles and the second nozzles is allowed to adhere directly to the substrates. With this, the liquid is allowed to adhere to the substrate more suitably than when the liquid is allowed to adhere to the substrates in a liquid atmosphere such as a mist. Furthermore, if the first nozzles and the second nozzles are disposed in a manner facing each other, the liquid mist sprayed from one of the first and the second nozzles may collide with that from the other, and lowers the efficiency at which the liquid is applied. Therefore, the plurality of first nozzles are disposed offset from the plurality of respective second nozzles by a distance corresponding to a half the second interval, in a direction in which the plurality of substrates are arranged. As a result, the collision of the liquid in the form of mist or the like is suppressed, and the liquid in the form of mist or the like is allowed to reach far into the space between the substrates. Therefore, it is possible to apply the liquid efficiently to the substrates. Furthermore, the liquid consumption can be reduced, so that the time for spraying can also be reduced.

Preferably, the substrate processing apparatus further includes a control unit, and the control unit is configured to cause the plurality of first nozzles and the plurality of second nozzles to alternately spray the liquid as the at least one of mist and droplets.

When the liquid is sprayed from two facing sides, the liquid sprayed as mist or the like from one side collides with that from the other, and this collision may prevent the liquid from adhering to the substrates. However, because the liquid is discharged from one side at a time, the collision is suppressed, so that the liquid such as a mist is allowed to reach far into the space between the substrates. Therefore, the liquid is allowed to adhere suitably to the substrates.

Furthermore, in the substrate processing apparatus described above, in a condition in which each of the plurality of first nozzles and the plurality of second nozzles is disposed facing a central axis passing through the plurality of substrates, each of the plurality of first nozzles and the plurality of second nozzles is configured to spray the liquid as the at least one of mist and droplets so that the liquid is delivered directly across a range from a proximal end to a center of facing substrate. As a result, the liquid is allowed to adhere on both surfaces (front surface and rear surface) of the substrate, across a wide area.

Preferably, the substrate processing apparatus described above further include: a lifting unit configured to move the substrate holder up and down; and a control unit, and the control unit is configured to cause the lifting unit to move the substrate holder up and down in such a manner that the plurality of substrates are passed between the plurality of first nozzles and the plurality of second nozzles, while the liquid is being sprayed from each of the plurality of first nozzles and the plurality of second nozzles. With this, the liquid is allowed to adhere directly to the substrates uniformly.

Preferably, the substrate processing apparatus further includes a relative actuator configured to move the substrate holder relatively with respect to the plurality of first nozzles and the plurality of second nozzles, along the direction in which the plurality of substrates are arranged. Because the substrate holder can be moved in the direction in which the substrates are arranged, the liquid is permitted to adhere directly to the substrates more uniformly.

In the substrate processing apparatus described above, the liquid is a solvent, for example. As another example, the liquid is a water repellent.

Preferably, the substrate processing apparatus described above further includes: a solvent supply unit capable of sending a solvent to each of the plurality of first nozzles and the plurality of second nozzles; and a water repellent supply unit capable of sending a water repellent to each of the plurality of first nozzles and the plurality of second nozzles, and, when the solvent supply unit is sending the solvent while the water repellent supply unit is not sending the water repellent, each of the plurality of first nozzles and the plurality of second nozzles sprays the solvent as at least one of mist and droplets, and when the water repellent supply unit is sending the water repellent while the solvent supply unit is not sending the solvent, each of the plurality of first nozzles and the plurality of second nozzles sprays the water repellent as the at least one of mist and droplets.

The solvent and the water repellent can be selectively discharged from the first nozzles and the second nozzles. Let us assume a configuration in which two rows of solvent nozzles and two rows of water repellent nozzles are disposed at different heights. If the substrates are passed between the two solvent nozzle rows while the solvent is being discharged, and the substrates are then passed between the two water repellent nozzle rows while the water repellent is being discharged, the distance by which the substrates are moved up and down may become extended. Therefore, the chamber may become large in height. According to the present invention, such an increase of the height of the chamber can be suppressed.

Preferably, the substrate processing apparatus further includes a processing tank provided inside the chamber and capable of storing a treatment liquid, and the plurality of first nozzles and the plurality of second nozzles are disposed at positions higher than the processing tank. Even with the processing tank provided inside the chamber, the liquid can be applied efficiently to the substrates.

With the substrate processing apparatus according to the present invention, a liquid can be applied efficiently to a substrate.

### BRIEF DESCRIPTION OF DRAWINGS

For the purpose of illustrating the invention, there are shown in the drawings several forms which are presently preferred, it being understood, however, that the invention is not limited to the precise arrangement and instrumentalities shown.

FIG. 1 is a longitudinal sectional view showing a schematic configuration of a substrate processing apparatus according to a first embodiment;

FIG. 2 is a diagram showing a layout of two rows of nozzles (mist nozzles), and how an IPA pipe and a water repellent pipe are laid;

FIG. 3 is a plan view showing an example of the positioning of the mist nozzles with respect to fifty substrates;

FIG. 4 is a diagram showing results of evaluating the liquid adhesion with different spray angles;

FIG. 5 is a diagram showing results of evaluating the liquid adhesion with different spray angles and second intervals (nozzle intervals);

FIG. 6 is a diagram for explaining an operation of the substrate processing apparatus according to the first embodiment;

FIG. 7 is a timing chart showing the operation of the substrate processing apparatus according to the first embodiment;

FIG. 8A is a diagram for explaining a configuration in which two pairs of mist nozzles are disposed facing each other, and FIG. 8B is a diagram for explaining a configuration in which two pairs of mist nozzles are offset from each another by a half pitch;

FIG. 9 is a diagram showing a layout of two rows of nozzles (mist nozzles) and how an IPA pipe and a water repellent pipe is laid in a second embodiment;

FIG. 10 is a plan view for explaining how the liquid is sprayed alternately from the mist nozzles in the second embodiment;

FIGS. 11A and 11B are plan views for explaining a lifter and two nozzle rows (mist nozzles) according to a modification; and

FIG. 12 is a side view showing mist nozzles and a holder according to the modification.

### DETAILED DESCRIPTION

### First Embodiment

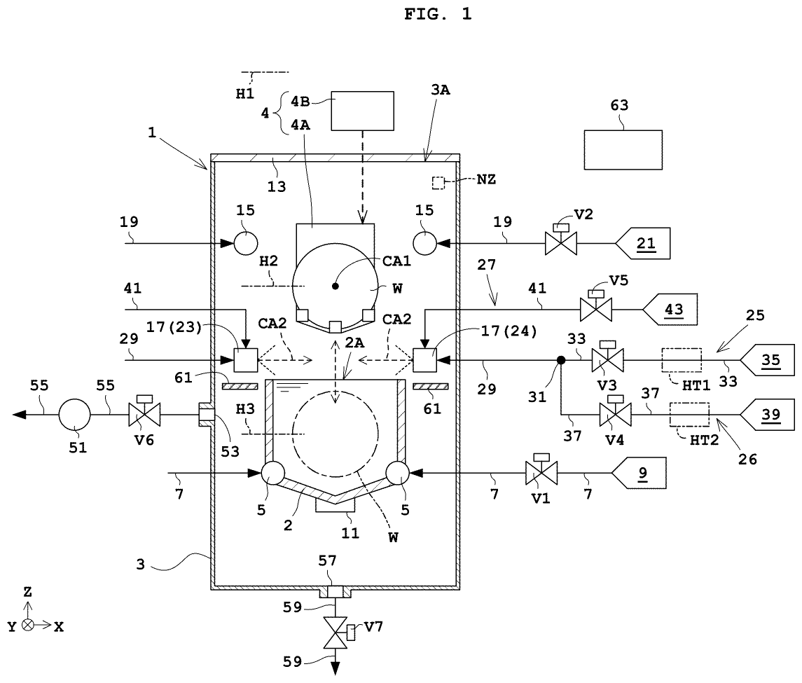

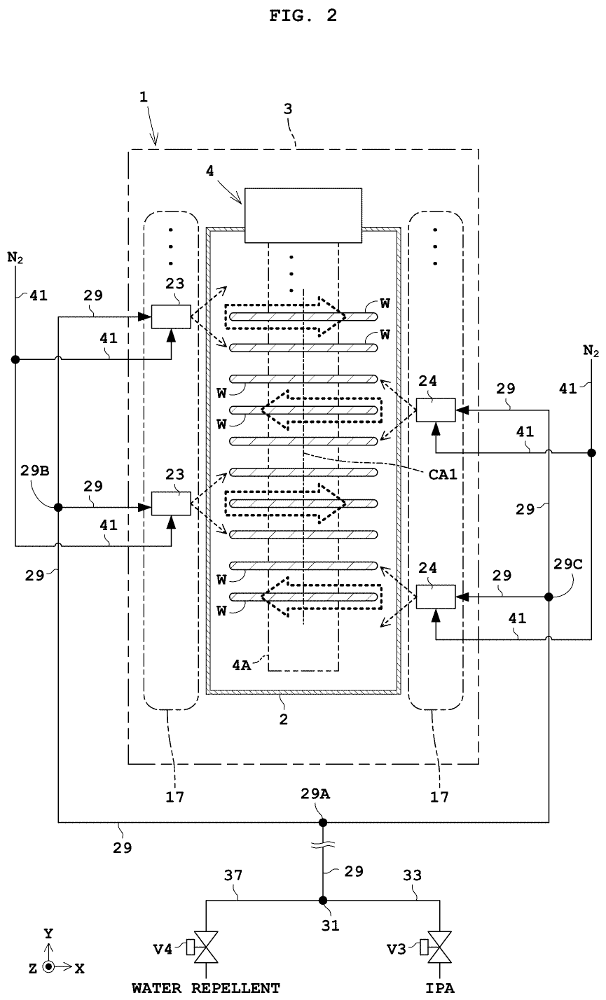

A first embodiment of the present invention will now be described with reference to drawings. FIG. 1 is a longitudinal sectional view showing a schematic configuration of a substrate processing apparatus 1 according to the first embodiment. FIG. 2 is a plan view showing a layout of two nozzle rows 17 (mist nozzles 23, 24), and how an IPA pipe and a water repellent pipe are laid.

### (1) Configuration of Substrate Processing Apparatus

FIG. 1 will now be referred to. The substrate processing apparatus 1 is configured to dry a plurality of (e.g., fifty or twenty-five) substrates W. Each of the substrates W has a disk-like shape, for example. A front surface (a fore surface or a principal surface) of each of the substrates W has a pattern such as that of elements. In this case, the surface opposite to the front surface of the substrate W will be referred to as a rear surface.

The substrate processing apparatus 1 includes a processing tank 2 capable of storing a processing liquid, a chamber 3 in which the processing tank 2 is housed, a lifter 4, and two spraying pipes 5. The processing tank 2 is disposed at a lower portion of the chamber 3, and is spaced apart from the bottom surface of the chamber 3. The processing tank 2 has an opening 2A on the top surface. The processing liquid overflown from the opening 2A is accumulated in the bottom part of the chamber 3. The chamber 3 houses a plurality of substrates W in the vertical orientation, in a manner arranged along the horizontal direction, with a predetermined first interval PH1 (e.g., 5 mm) therebetween.

The lifter 4 moves the plurality of substrates W up and down inside the chamber 3, by holding the plurality of substrates W. The lifter 4 includes a holder 4A for holding the plurality of substrates W in the vertical orientation, and a lifting unit 4B for moving the holder 4A up and down in the vertical direction (Z direction). The plurality of substrates W held by the holder 4A are arranged at equal intervals in the thickness direction of the substrates W. For example, in FIG. 1, the direction in which the plurality of substrates W are arranged is the Y direction. The holder 4A is provided inside the chamber 3. The holder 4A corresponds to a substrate holder according to the present invention. The lifting unit 4B corresponds to a lifting unit according to the present invention.

The lifting unit 4B includes an electric motor, for example. The lifting unit 4B can move the plurality of substrates W held by the holder 4A between a transfer position H1 above the chamber 3, for example, an upper position H2 above the processing tank 2 inside the chamber 3, and a lower position (immersion processing position) H3 inside the processing tank 2.

The two spraying pipes 5 for supplying the processing liquid into the processing tank 2 are provided to the bottom of the processing tank 2. Each of the spraying pipes 5 has a linear shape extending in the Y direction, which is the direction in which the plurality of substrates W are arranged. Each of the spraying pipes 5 has a plurality of spray ports arranged in the Y direction.

A processing liquid pipe 7 has a tip end that is branched into two. The two tip ends of the processing liquid pipe 7 are then connected to the two spraying pipes 5, respectively. The processing liquid pipe 7 has a base end connected to a processing liquid source 9. The processing liquid source 9 sends pure water, for example, as a processing liquid, to the processing liquid pipe 7. As the pure water, deionized water (DIW) is used, for example. The processing liquid pipe 7 is provided with an on-off valve V1. The on-off valve V1 is for supplying and stopping the supply of the pure water. For example, when the on-off valve V1 is opened, the pure water is supplied from the two spraying pipes 5. When the on-off valve V1 is closed, the supply of pure water from the two spraying pipes 5 is stopped.

As the processing liquid, it is also possible to use diluted isopropyl alcohol (IPA) liquid, which is IPA liquid diluted with pure water. The two spraying pipes 5 may be enabled to discharge pure water and diluted IPA liquid selectively.

The substrate processing apparatus 1 also includes a QDR valve (on-off valve) 11 provided to the bottom of the processing tank 2. The QDR valve 11 releases the pure water inside the processing tank 2 onto the bottom surface of the chamber 3. When the QDR valve 11 is opened, the pure water in the processing tank 2 is quickly discharged to the bottom of the chamber 3. When the QDR valve 11 is closed, the pure water can be kept inside the processing tank 2.

The chamber 3 has an opening 3A through which the plurality of substrates W are passed, and a top cover 13 that closes the opening 3A. The opening 3A is provided to the ceiling of the chamber 3. When the top cover 13 is opened, a plurality of substrates W can be passed through the opening 3A. When the top cover 13 is closed, the space inside the chamber 3 is closed. The top cover 13 is opened and closed by an electric motor (not shown).

The substrate processing apparatus 1 also includes two inert gas nozzles 15 and two nozzle rows 17. The two inert gas nozzles 15 and the two nozzle rows 17 are provided inside the chamber 3. The two inert gas nozzles 15 and the two nozzle rows 17 are arranged between the top cover 13 and the processing tank 2, in the order listed herein from the above. The two nozzle rows 17 (mist nozzles 23, 24 to be described later) are arranged at positions higher than the processing tank 2, that is, higher than the opening 2A of the processing tank 2. The two nozzle rows 17 may be disposed near the outer edge of the opening 2A of the processing tank 2, that is, near the upper end of the side wall of the processing tank 2. The two nozzle rows 17 may spray solvent mist in a direction from an outer side toward an inner side of the processing tank 2 (or the opening 2A), in plan view.

Each of the two inert gas nozzles 15 supplies inert gas into the chamber 3. A supply pipe 19 has a tip end that is branched into two. The two tip ends of the supply pipe 19 are then connected to the two inert gas nozzles 15, respectively, as shown in FIG. 1. The base end of the supply pipe 19 is connected to a first inert gas source 21. The first inert gas source 21 sends nitrogen gas, for example, as an inert gas to the supply pipe 19. The supply pipe 19 is provided with an on-off valve V2. The on-off valve V2 supplies and stops the supply of the inert gas.

FIG. 2 will now be referred to. A first nozzle row 17 has a plurality of (e.g., nine) mist nozzles 23 that are arranged along the Y direction. A second nozzle row 17 has a plurality of (e.g., nine) mist nozzles 24 that are arranged along the Y direction. Each of these two nozzle rows 17 sprays solvent mist and water repellent mist selectively into the chamber 3. That is, each of the eighteen mist nozzles 23, 24 discharges liquid (solvent or water repellent) in the form of mist, for example. As each of the mist nozzle 23, a nozzle having the same structure as each mist nozzle 24 is used. Each of the mist nozzles 23, 24 is a two-fluid nozzle. The two-fluid nozzle is a nozzle that mixes inert gas with liquid (solvent or water repellent), and sprays the mist of the liquid. That is, the two-fluid nozzle discharges (sprays) the solvent or the water repellent as mist.

The mist nozzles 23 correspond to first nozzles according to the present invention. The mist nozzles 24 correspond to second nozzles according to the present invention. The mist nozzles 24 may also be the first nozzles according to the present invention, and the mist nozzles 23 may be the second nozzles according to the present invention.

As shown in FIG. 1, the substrate processing apparatus 1 further includes a solvent supply unit 25, a water repellent supply unit 26, and an inert gas supply unit 27. The solvent supply unit 25 is capable of sending the solvent (liquid) to each of the mist nozzles 23, 24. The water repellent supply unit 26 is capable of sending the water repellent (liquid) to each of the mist nozzles 23, 24. As shown in FIGS. 1 and 2, a common pipe 29 has a tip end thereof connected to the mist nozzles 23, 24 (two nozzle rows 17). In a configuration in which the two nozzle rows 17 has eighteen mist nozzles 23, 24, for example, the tip end of the common pipe 29 is branched into eighteen. The eighteen tip ends are then connected to the eighteen mist nozzles 23, 24, respectively, for example. A base end of the common pipe 29 is connected to a junction pipe 31 (e.g., a T-pipe).

The solvent supply unit 25 includes a solvent pipe 33, an on-off valve V3, and a heater HT1. A tip end of the solvent pipe 33 is connected to the junction pipe 31, and a base end thereof is connected to a solvent source 35. The solvent source 35 sends isopropyl alcohol (IPA) liquid, as an example, as a solvent (organic solvent), to the solvent pipe 33. The solvent is preferably hydrophilic. The on-off valve V3 is provided to the solvent pipe 33. The on-off valve V3 is for supplying and stopping the supply of the solvent. The heater HT1 is provided to the solvent pipe 33, at a position between the on-off valve V3 and the solvent source 35. For example, the heater HT1 heats the solvent passing through the solvent pipe 33 to a predetermined temperature, from outside of the solvent pipe 33.

The water repellent supply unit 26 includes a water repellent pipe 37, an on-off valve V4, and a heater HT2. The water repellent pipe 37 has a tip end connected to the junction pipe 31, and a base end connected to the water repellent source 39. The water repellent source 39 sends the water repellent (liquid) into the water repellent pipe 37. The water repellent modifies the surface of the substrate W so as to provide the surface with water repellency. As the water repellent, a silicon-based water repellent or a metal-based water repellent is used, for example. The water repellent is also referred to a silylating agent. The on-off valve V4 is provided to the water repellent pipe 37. The on-off valve V4 is for supplying and stopping the supply of the water repellent. The heater HT2 is provided to the water repellent pipe 37, at a position between the on-off valve V4 and the water repellent source 39. For example, the heater HT2 heats the water repellent passing through the water repellent pipe 37 to a predetermined temperature, from outside of the water repellent pipe 37.

The solvent supply unit 25 and the water repellent supply unit 26 may be provided with a pump, not shown. The common pipe 29 may be provided to one of the solvent supply unit 25 and the water repellent supply unit 26.

The inert gas supply unit 27 is capable of sending an inert gas to each of the mist nozzles 23, 24. The inert gas supply unit 27 includes an inert gas supply pipe 41 and an on-off valve V5. A tip end of the inert gas supply pipe 41 is connected to the mist nozzles 23, 24 (two nozzle rows 17). In the configuration in which the two nozzle rows 17 has eighteen mist nozzles 23, 24, for example, the tip end of the inert gas supply pipe 41 is branched into eighteen. The eighteen tip ends of the inert gas supply pipe 41 are then connected to the eighteen mist nozzles 23, 24, respectively, for example. A base end of the inert gas supply pipe 41 is connected to a second inert gas source 43. The second inert gas source 43 sends nitrogen gas as an inert gas, for example. The inert gas supply pipe 41 is provided with an on-off valve V5. The on-off valve V5 is for supplying and stop supplying the inert gas.

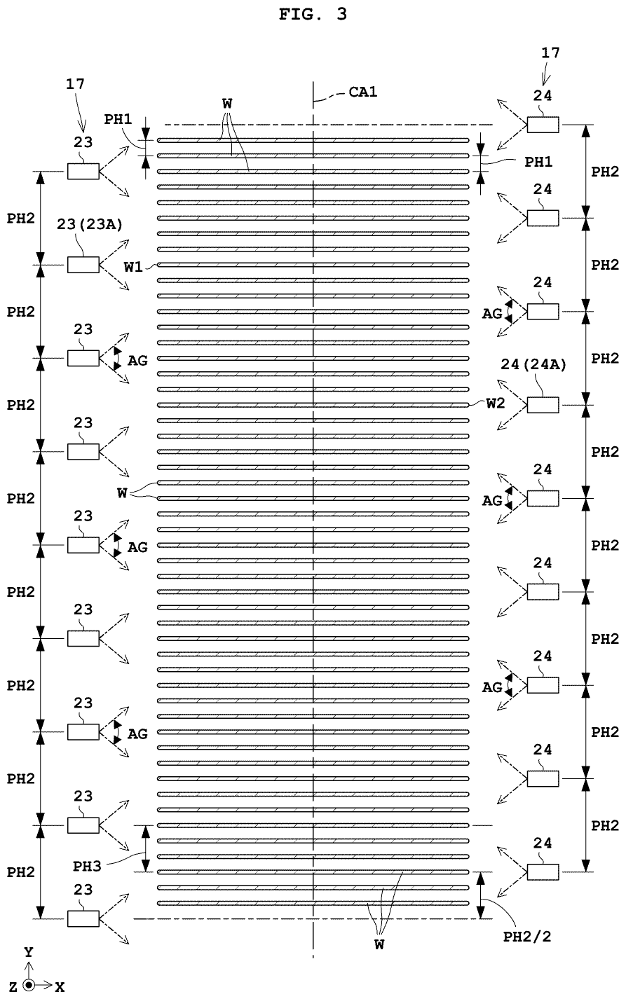

FIG. 3 is a plan view showing an example of the positioning of the mist nozzles 23, 24 with respect to a plurality of (e.g., fifty) substrates W. The plurality of (e.g., nine) mist nozzles 23 are arranged at a predetermined second interval PH2, along the arrangement of the plurality of (e.g., fifty) substrates W. Similarly, the plurality of (e.g., nine) mist nozzles 24 are arranged at the second interval PH2, along the arrangement of the plurality of (e.g., fifty) substrates W.

The nine mist nozzles 23 are disposed facing the nine mist nozzles 24, with the fifty substrates W therebetween in plan view. In other words, the nine mist nozzles 23 are disposed opposite to the nine mist nozzles 24 across the fifty substrates W in plan view. That is, the nine mist nozzles 23 (first nozzle row 17), the fifty substrates W, and the nine mist nozzles 24 (second nozzle row 17) are arranged in the order described herein along the X direction, as shown in FIG. 3. The nine mist nozzles 23 (first nozzle row) are arranged at the same height position as the nine mist nozzles 24 (second nozzle row 17).

The eighteen mist nozzles 23, 24 are disposed in a manner facing the fifty substrates W in plan view. That is, the eighteen mist nozzles 23, 24 are disposed in a manner facing inwards, in a direction from the outer side of the processing tank 2, the opening 2A, and the chamber 3 in plan view. The nine mist nozzles 23 face in the same direction. Similarly, the nine mist nozzles 24 face in the same direction. In the present embodiment, the nine mist nozzles 23 all face the +X direction (right side in FIG. 1). The nine mist nozzles 24 all faces the −X direction (left side in FIG. 1).

The nine mist nozzles 23 are arranged in a manner offset from the nine respective mist nozzles 24 by a length PH3 (=PH2/2) that is approximately a half the second interval PH2, in the direction in which the fifty substrates W are arranged (Y direction). The direction in which the nozzles are offset may be either one of the directions along which the fifty substrates W are arranged. The second interval PH2 is wider than the first interval PH1 (e.g., 5 mm) that is the interval between the fifty substrates W. The second interval PH2 is, for example, 30 mm. Therefore, the nine mist nozzles 23 are disposed in a manner offset from the nine mist nozzles 24 by 15 mm in the Y direction. That is, the eighteen mist nozzles 23, 24 are arranged in a zigzag shape, as shown in FIG. 3.

Each of the eighteen mist nozzles 23, 24 has a spray angle (discharge angle) AG of 45 degrees, for example. The spray has a conical or fan-like shape. The fan-shaped spray pattern is a pattern in which the spray spreads in the vertical direction (Z direction) by a degree smaller than that in the horizontal direction (Y direction). In the plan view of FIGS. 1 to 3, each of a gap between the nine mist nozzles 23 and the fifty substrates W and a gap between the nine mist nozzles 24 and the fifty substrates W is, for example, 26 mm.

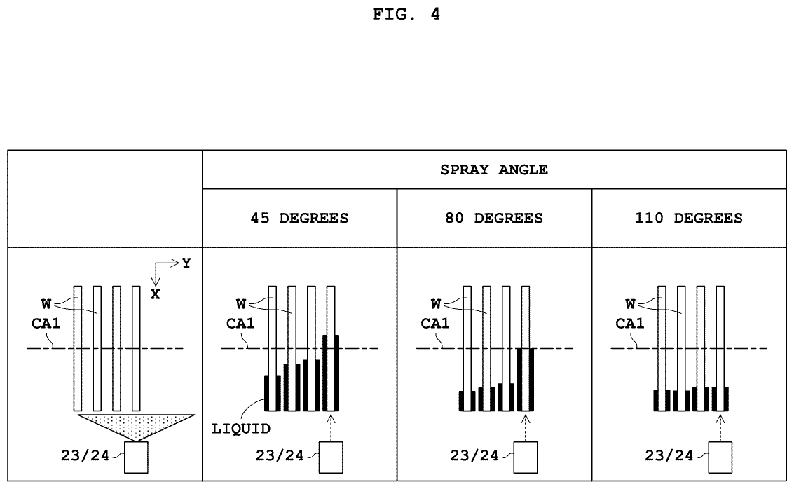

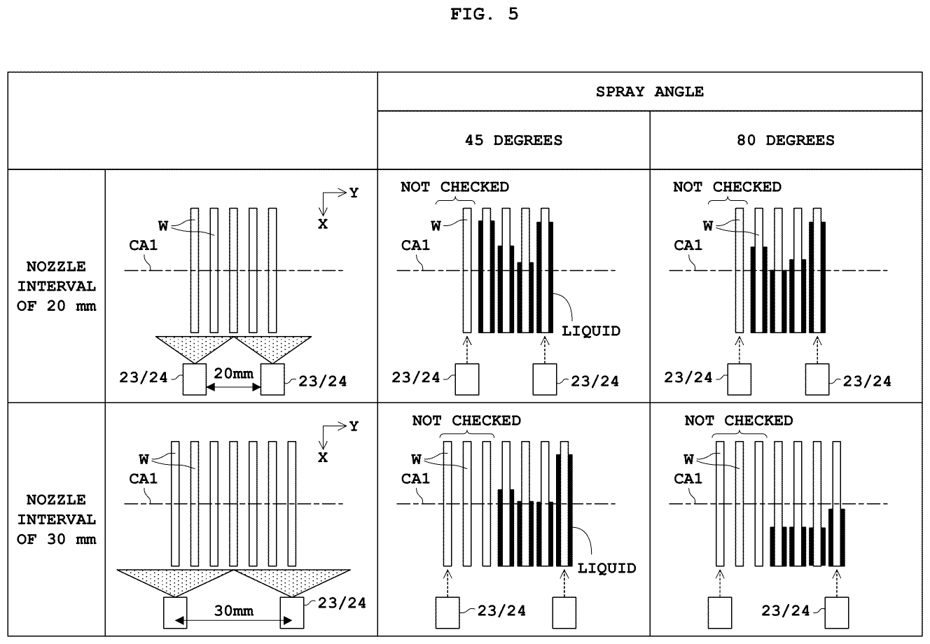

The spray angle (discharge angle) AG and the second interval PH2 will now be described with reference to the evaluation results shown in FIGS. 4 and 5.

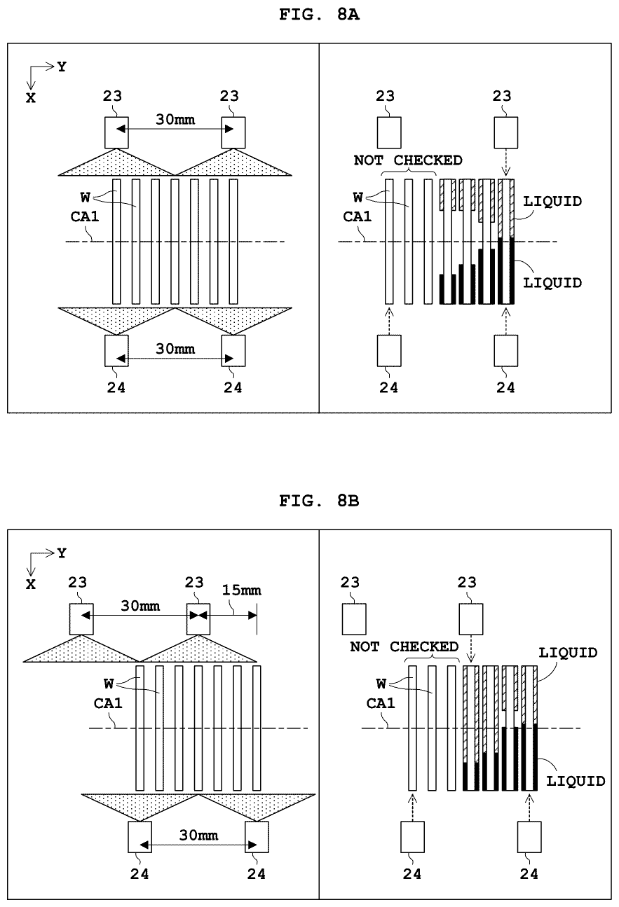

FIG. 4 is a diagram illustrating results of evaluating the liquid adhesion with different spray angles AG. In FIG. 4, the adhesion of the liquid was compared under three conditions of spray angles AG of 45 degrees, 80 degrees, and 110 degrees. DIW mist was then sprayed by supplying the air at 5 L/min (liter/min) and supplying DIW at 15 mL/min (milliliter/min) to each of the mist nozzles 24 (23). The same flow rates were also used in FIG. 5 and FIGS. 8A and 8B, to be described later. In FIG. 4, with the spray angle AG of 110 degrees, the liquid (DIW) did not adhere up to the center (did not reach a central axis CA1) of the substrates W. With the spray angle AG of 45 degrees, the liquid adhered across a range from the proximal end to the center of facing substrate W, as well as the widest areas on the front and the rear surfaces of the four substrates W in FIG. 4.

FIG. 5 is a diagram illustrating results of evaluating the liquid adhesion with different spray angles AG and second intervals PH2 (nozzle intervals). In FIG. 5, the adhesion of the liquid was compared under four conditions of spray angles AG of 45 degrees and 80 degrees, and the second intervals PH2 of 20 mm and 30 mm between the two mist nozzles 24 (23). On the basis of FIG. 5, the results indicated that a narrower second interval PH2 is more preferable, and a smaller spray angle AG is more preferable.

Hence, a spray angle AG of 45 degrees and a second interval PH2 of 20 mm or more and 30 mm or less are preferable. Furthermore, with a spray angle AG of 45 degrees, a second interval PH2 of 25 mm or more and 30 mm or less is more preferable. This is because, when the second interval PH2 is smaller, the number of mist nozzles 23, 24 increases, and a larger amount of liquid is consumed by spraying. If the second interval PH2 is wider than 30 mm, it becomes difficult for the liquid to adhere up to the center of the one or more substrates W positioned between the two mist nozzles 23 (24) shown in FIG. 5. As shown in FIG. 5, when the spray angle AG is 45 degrees and the second interval PH2 is 20 mm or 30 mm, the liquid adhered up to the center of the one or more substrates W positioned between the two mist nozzles 23 (24). With the second interval PH2 of 20 mm, a spray angle AG of 45 degrees or more and 80 degrees or less is preferable.

In FIG. 3, eighteen mist nozzles 23, 24 are provided, with the spray angle AG set to 45 degrees and the second interval PH2 set to 30 mm. In this regard, twenty-two mist nozzles 23, 24 (eleven mist nozzles 23 and eleven mist nozzles 24) may be provided by, for example, setting the spray angle AG to 45 degrees, with a second interval PH2 of 25 mm.

The description goes back to that of the substrate processing apparatus 1. The substrate processing apparatus 1 includes an evacuation pump (decompression pump) 51. On a side wall of the chamber 3, an evacuation port 53 is provided. The evacuation port 53 is disposed below a shield plate 61, which will be described later. An evacuation pipe 55 is connected to the evacuation port 53. The evacuation pipe 55 is provided with an on-off valve V6 and the evacuation pump 51, in the order listed herein, from the side of the evacuation port 53. The evacuation pump 51 reduces the pressure inside of the chamber 3 by evacuating the gas inside the chamber 3.

On the bottom wall of the chamber 3, a discharge port 57 is provided. A discharge pipe 59 is connected to the discharge port 57. The discharge pipe 59 is provided with an on-off valve V7. When the on-off valve V7 is opened, liquid such as a processing liquid accumulated in the bottom of the chamber 3 is discharged through the discharge port 57 and the discharge pipe 59. When the on-off valve V7 is closed, the liquid such as the processing liquid remains without being discharged from the inside of the chamber 3.

The chamber 3 includes the shield plate 61. The shield plate 61 partitions the chamber 3 into an upper space and a lower space. The shield plate 61 is provided slightly below the upper end of the processing tank 2 (or the opening 2A). The shield plate 61 is provided in a manner surrounding the processing tank 2. There is a gap between the shield plate 61 and the outer wall of the processing tank 2, and between the shield plate 61 and the inner wall of the chamber 3. The processing liquid, the gas, and the solvent mist flow through the gap.

The substrate processing apparatus 1 includes a control unit 63 and a storage unit (not shown). The control unit 63 controls each component included in the substrate processing apparatus 1. The control unit 63 includes one or more processors such as a central processing unit (CPU). The storage unit includes at least one of a read-only memory (ROM), a random-access memory (RAM), and a hard disk, for example. The storage unit stores therein a computer program required in controlling each of the components included in the substrate processing apparatus 1.

For example, the control unit 63 causes the lifting unit 4B to move the holder 4A up and down so that fifty substrates W are passed between the nine mist nozzles 23 and the nine mist nozzles 24.

### (2) Operation of Substrate Processing Apparatus 1

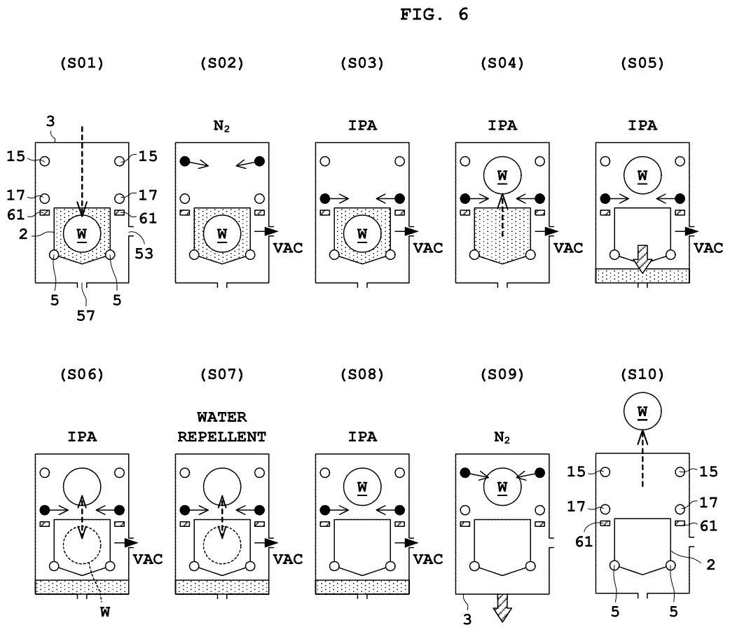

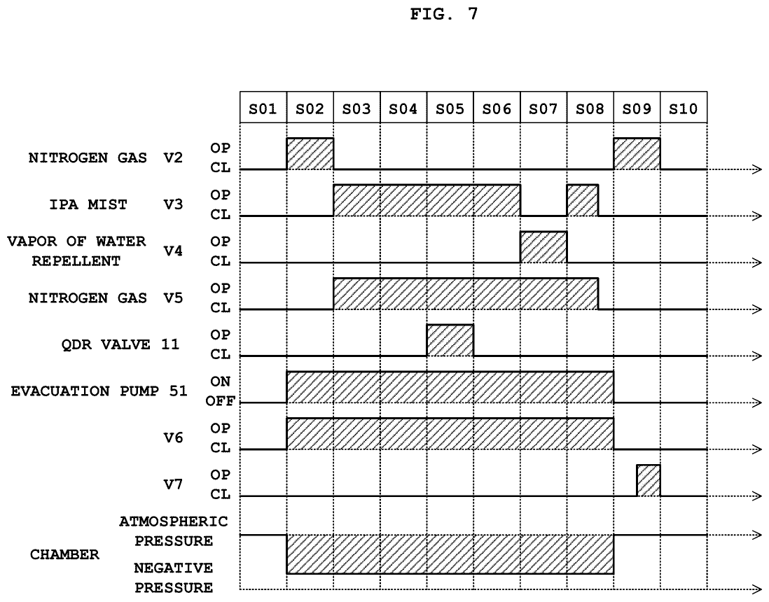

An operation of the substrate processing apparatus 1 will now be described with reference to FIGS. 6 and 7. In FIG. 6, the lifter 4 is not shown. In FIG. 6, the reference sign VAC denotes an evacuating operation (exhaust operation) of the evacuation pump 51 or the like. In FIG. 7, the reference numeral CL indicates that the on-off valve V2 or the like is closed, and the reference numeral OP indicates that the on-off valve V2 or the like is open. The plurality of (e.g., 50) substrates W will be referred to as “substrates W”, as appropriate.

[Step S01] Immersion Processing (Deliver Substrates into Chamber)

In the processing tank 2, pure water is stored as a processing liquid. The pure water is supplied from the spraying pipes 5. The holder 4A of the lifter 4 receives a plurality of substrates W from a transfer robot, not shown, at the transfer position H1. The lifter 4 moves the substrates W downwards from the transfer position H1 to the lower position H3 in the processing tank 2. That is, the lifter 4 immerses the entire substrates W in the pure water inside the processing tank 2. By immersing the substrates W in the pure water, the substrates W are cleaned, and are prevented from becoming dry. The opening 3A of the chamber 3 is then closed with the top cover 13.

[Step S02] Evacuation of Gas from Chamber

The on-off valve V2 is then opened, and the nitrogen gas is supplied from the inert gas nozzles 15 into the chamber 3. While the substrates W are immersed in the processing liquid, the evacuation pump 51 reduces the pressure inside of the chamber 3. In other words, the on-off valve V6 is opened while operating the evacuation pump 51 so that the gas inside the chamber 3 is evacuated through the evacuation port 53 and the evacuation pipe 55. As a result, the pressure inside of the chamber 3 is reduced a pressure lower than the atmospheric pressure (negative pressure).

The evacuation pump 51 is kept operated during steps S02 to S08. Similarly, the on-off valve V6 is kept open during steps S02 to S08. In steps S02 to S08, the internal pressure of the chamber 3 is kept to the negative pressure.

### [Step S03] First IPA Spraying (Creating IPA Mist Atmosphere)

The on-off valve V2 is then closed to stop the supply of the nitrogen gas from the inert gas nozzles 15. While the internal pressure of the chamber 3 is reduced, with the substrates W immersed in the processing liquid, IPA mist is sprayed from the two nozzle rows 17 (eighteen mist nozzles 23, 24). That is, the on-off valves V3 and V5 are opened, and the IPA mist is sprayed from the two nozzle rows 17 into the chamber 3. As a result, an atmosphere of mist IPA is created inside of the chamber 3. During steps S03 to S06, the on-off valves V3 and V5 are kept open.

The pure water in the processing tank 2 may come to contain the IPA mist. Therefore, it can also be said that the IPA liquid becomes diluted with pure water in the processing tank 2. As a result, in step S04 described later, when the substrates W are taken out of the pure water containing IPA in the processing tank 2, it is possible to promote replacement of the pure water adhering to the substrates W with the IPA liquid.

### [Step S04] First IPA Spraying (Pulling Up Substrates)

The inside chamber 3 is then kept to the negative pressure and the IPA mist (the solvent) is kept being sprayed. In this condition, the lifter 4 pulls up the substrates W from the pure water in the processing tank 2. That is, the lifter 4 moves the substrates W upwards from the lower position H3 to the upper position H2. At this time, the substrates W are passed between the two nozzle rows 17. The IPA mist being sprayed from the two nozzle rows 17 is thus enabled to adhere directly to the substrates W. As a result, a replacement process in which the pure water adhering on the substrates W becomes replaced with the IPA takes place. As the substrates W are then exposed to the IPA mist atmosphere, the replacement process proceeds further.

Alternatively, in step S04, it is also possible to stop the evacuation pump 51 and close the on-off valve V6. In this manner, the negative pressure is maintained.

[Step S05] First IPA Spraying (Releasing Pure Water from Processing Tank)

The IPA mist is kept being sprayed while maintaining the negative pressure inside the chamber 3. In such a condition, the QDR valve 11 is opened so that the pure water is discharged quickly from the processing tank 2 to the bottom surface in the chamber 3. After the processing tank 2 is emptied, the QDR valve 11 is closed.

### [Step S06] First IPA Spraying (Moving Substrates Up and Down)

The lifting unit 4B in the lifter 4 moves the holder 4A holding the fifty substrates W up and down while the IPA mist is being sprayed from each of the eighteen mist nozzles 23, 24 so as to pass the fifty substrates W between the nine mist nozzles 23 and the nine mist nozzles 24.

In other words, while passing the fifty substrates W between the two nozzle rows 17 spraying the IPA mist, the lifter 4 moves the fifty substrates W downwards from the upper position H2 to the lower position H3 in the processing tank 2 with no pure water being stored, and then moves the fifty substrates W upwards from the lower position H3 to the upper position H2. This operation of moving the substrates up and down is performed once or a plurality of times (e.g., three times). In this manner, the IPA is permitted to adhere directly and uniformly to the substrates W. In addition, when the operation of moving substrates up and down is repeated more, the IPA is allowed to adhere less unevenly.

The eighteen mist nozzles 23, 24 are configured in such a manner that, with each of the eighteen mist nozzles 23, 24 facing the direction of the center axis CA1 passing through the center of the substrates W, the IPA mist is delivered directly across a range from a proximal end to the center of facing substrate W. In this manner, as the fifty substrates W are passed between the two nozzle rows 17 (mist nozzles 23, 24), it is possible to attach (apply) the IPA mist sprayed from the mist nozzles 23, 24, not the IPA mist drifting inside the chamber 3, directly to the center of each of the substrates W in plan view. In addition, it is possible to attach the IPA across a wide area on both of the surfaces (the front surfaces and the rear surface) of the substrates W. For example, in FIG. 3, a mist nozzle 23A faces a substrate W1, and a mist nozzle 24A faces a substrate W2.

### [Step S07] Spraying Water Repellent

The evacuation of the air inside the chamber 3 is then continued. By then closing the on-off valves V3 and V5, the supply of the IPA mist from the two nozzle rows 17 is stopped. By then opening the on-off valves V4 and V5, the water repellent mist is then sprayed from the nozzle rows 17 (eighteen mist nozzles 23, 24) into the chamber 3. At this time, the lifting unit 4B of the lifter 4 moves the holder 4A holding the fifty substrates W up and down so that the fifty substrates W are passed between the nine mist nozzles 23 and the nine mist nozzles 24. That is, the lifter 4 moves the substrates W up and down between the upper position H2 and the lower position H3. As a result, the water repellent mist is uniformly attached to the entire substrate W. By spraying the water repellent mist, the IPA adhering to the substrates W is replaced with the water repellent. The water repellent modifies the surface of the substrate W so as to provide the surface with water repellency. Therefore, pattern collapsing can be prevented suitably.

### [Step S08] Second IPA Spraying, and Drying

After spraying of the water repellent mist is stopped, the two nozzle rows 17 are caused to spray the solvent mist. This operation will now be explained specifically. After step S07, the evacuation of the air inside the chamber 3 is continued. By closing the on-off valves V4 and V5, spraying of the water repellent mist from the two nozzle rows 17 is stopped. By then opening the on-off valves V3 and V5, spray of the IPA mist is supplied from the two nozzle rows 17. In this manner, the water repellent adhering on the substrates W is replaced with IPA. In other words, the water repellent adhering to the substrates W is washed away with the IPA. Particles adhering on the substrate W, the particles originating from the water repellent, are also washed away with the IPA. These particles are formed by the water repellent coming into direct contact with moisture, for example.

The lifting unit 4B in the lifter 4 may be configured to move the holder 4A holding the fifty substrates W up and down while the IPA mist is being sprayed from each of the eighteen mist nozzles 23, 24 so that the fifty substrates W are passed between the nine mist nozzles 23 and the nine mist nozzles 24. The lifter 4 may be also configured to move the substrates W up and down between the upper position H2 and the lower position H3.

The on-off valves V3 and V5 are then closed to stop the supply of the IPA mist from the two nozzle rows 17. As a result, the IPA adhering on the substrates W volatilizes and the substrates W are dried inside the chamber 3 with the negative internal pressure. It is also possible to supply nitrogen gas from the inert gas nozzles 15 while the substrates W are being dried.

### [Step S09] Supplying Nitrogen Gas

The evacuation pump 51 is then stopped, and the on-off valve V6 is closed. The on-off valve V2 is also opened to supply the nitrogen gas from the inert gas nozzles 15. As a result, the negative internal pressure of the chamber 3 is gradually brought back to the atmospheric pressure. By then opening the on-off valve V7, the pure water is released from the bottom of the chamber 3.

[Step S10] Transporting Substrates from Chamber

The top cover 13 is then opened to open the opening 3A. The lifter 4 moves the substrates W being held by the holder 4A upwards from the upper position H2 to the transfer position H1. The substrates W having been moved upwards to the transfer position H1 are then moved to the next destination by the transfer robot, not shown.

According to the present embodiment, mainly mist of the liquid (IPA or water repellent) sprayed from the mist nozzles 23, 24 adheres directly to the substrate W. With this, the liquid is allowed to adhere to the substrates W more suitably than when the liquid is allowed to adhere to the substrates W in a liquid mist atmosphere. Furthermore, the mist of the liquid sprayed from each of the mist nozzles 23, 24 is more likely to be discharged more straightly, so that it is possible to deliver the mist of the liquid farther forwards. In a configuration in which the nine mist nozzles 23 are disposed facing the nine mist nozzles 24, respectively, the mist of the liquid from one of the nine mist nozzles 23 and the nine mist nozzles 24 collides with that sprayed from the other, and this collision may deteriorate the application efficiency (see FIG. 8A). Therefore, the nine mist nozzles 23 (first nozzle row 17) are arranged in a manner offset from the nine mist nozzles 24 (second nozzle row 17) by a length corresponding to a half the second interval PH2 (PH2/2), in the direction in which the fifty substrates W are arranged. As a result, the collision of the liquid in the form of mist is suppressed, and the liquid mist is allowed to reach far into the space between the substrates (see FIG. 8B). Therefore, the liquid can be applied efficiently to the substrates W. Furthermore, the liquid consumption can be reduced, so that the time for spraying can also be reduced.

Furthermore, the mist nozzles 23, 24 is enabled to spray the IPA and the water repellent selectively. For example, let us suppose a configuration in which two solvent nozzle rows and two water repellent nozzle rows are disposed at different heights. If the substrates W are passed between the two solvent nozzle rows while the IPA is being discharged and are passed between the two water repellent nozzle rows while the water repellent is being discharged, the distance by which the substrates W are lifted and lowered may become extended. This may lead to an increased height of the chamber 3. However, according to the present embodiment, an increase in the height of the chamber 3 can be suppressed.

### Second Embodiment

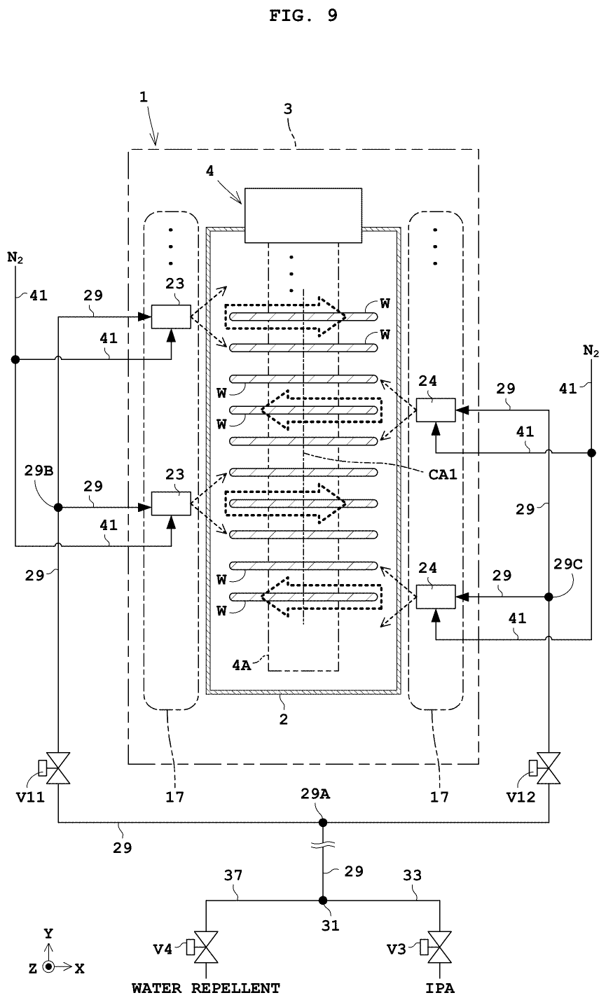

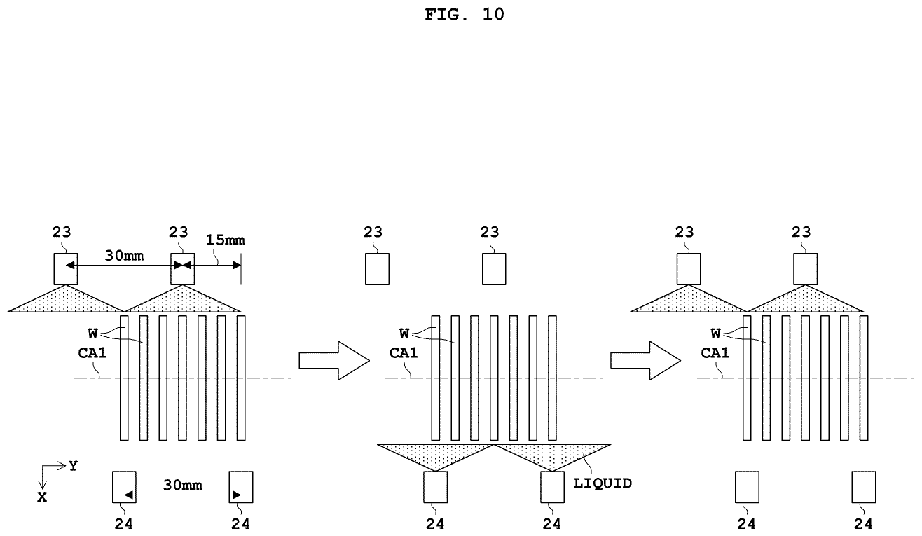

A second embodiment of the present invention will now be described with reference to drawings. Here, the description common to that of the first embodiment is to be omitted. FIG. 9 is a diagram illustrating a layout of the two nozzle rows 17 (mist nozzles 23, 24) and how the IPA pipe and the water repellent pipe are laid. FIG. 10 is a diagram for explaining how the liquid is sprayed alternately from the mist nozzles 23, 24.

In the first embodiment, the IPA mist is sprayed from all of the eighteen mist nozzles 23, 24 simultaneously. In this regard, in the second embodiment, the nine mist nozzles 23 (first nozzle row) and the nine mist nozzles 24 (second nozzle row) spray the IPA mist alternately.

FIG. 9 will now be referred to. The substrate processing apparatus 1 further includes two on-off valves V11, V12. The on-off valve V11 is provided to the common pipe 29, at a position between a branch pipe 29A and a branch pipe 29B. The on-off valve V12 is provided to the common pipe 29, at a position between the branch pipe 29A and a branch pipe 29C. The branch pipe 29A (e.g., a T-pipe) forms a branch branching to the side of the nine mist nozzles 23 and to the side of nine mist nozzles 24. The branch pipe 29B is a most upstream portion further branching into the respective mist nozzles 23. The branch pipe 29C is a most upstream portion further branching to the respective mist nozzles 24.

A spraying operation according to the present embodiment will now be described. In the beginning, the on-off valves V3 to V5, V11, and V12 are closed. When the IPA is then to be sprayed, for example, the two on-off valves V11, V12 are opened alternately while the on-off valves V3, V5 are kept open, that is, in a manner allowing the IPA liquid and the nitrogen gas to be sent to the mist nozzles 23, 24. Specifically, the on-off valve V12 is closed while the on-off valve V11 is open; and the on-off valve V11 is closed while when the on-off valve V12 is open. By operating in the manner described above, the IPA mist is sprayed alternately from the nine mist nozzles 23 and the nine mist nozzles 24, as illustrate in FIG. 10.

The same applies to the case of spraying the water repellent. The two on-off valves V11 and V12 are opened alternately while the on-off valves V4, V5 are kept open. In this manner, the water repellent mist is sprayed from the nine mist nozzles 23 and the nine mist nozzles 24, alternately.

In the present embodiment, if a liquid (IPA or a water repellent) is sprayed from both sides of the eighteen mist nozzles 23, 24 at the same time, flows of the mist of the liquid or gas containing the mist of the liquid collides with each other, and the liquid may be hindered from adhering to the substrates W. However, because the liquid is discharged from each side at a time, the collision is suppressed, so that the mist is allowed to reach far into the space between the substrates W. Therefore, the liquid is allowed to adhere to the substrates W, suitably.

The present invention is not limited to the embodiments described above, and following modifications are still possible.

(1) In the embodiments described above, the two nozzle rows 17 shown in FIG. 3 are provided with the mist nozzles 23, 24. In this regard, the two nozzle rows 17 may be provided with, instead of the mist nozzles 23, 24, a plurality of shower heads (shower nozzles) that spray the liquid (IPA or water repellent) in the form of droplets. The plurality of shower heads are also arranged in a zigzag shape, as shown in FIG. 3. Each of the shower heads does not discharge the solvent linearly and continuously, but rather discharges droplets. The showerhead is also referred to as a one-fluid nozzle. The two nozzle rows 17 may be configured to supply a solvent as at least one of mist and droplets.

(2) In the embodiments described above, the mist nozzles 23, 24 are provided as two-fluid nozzles. In this respect, the mist nozzles 23, 24 may be provided as one-fluid nozzles. A one-fluid nozzle is a nozzle turning liquid into mist using the pressure of the liquid, without using gas.

(3) In the embodiments and modifications described above, for example, the lifter 4 may further include a Y-direction actuator 4C configured to move the holder 4A in directions in which the fifty substrates W are arranged (Y direction), with respect to the mist nozzles 23, 24 of the two nozzle rows 17. The Y-direction actuator 4C includes an electric motor, for example.

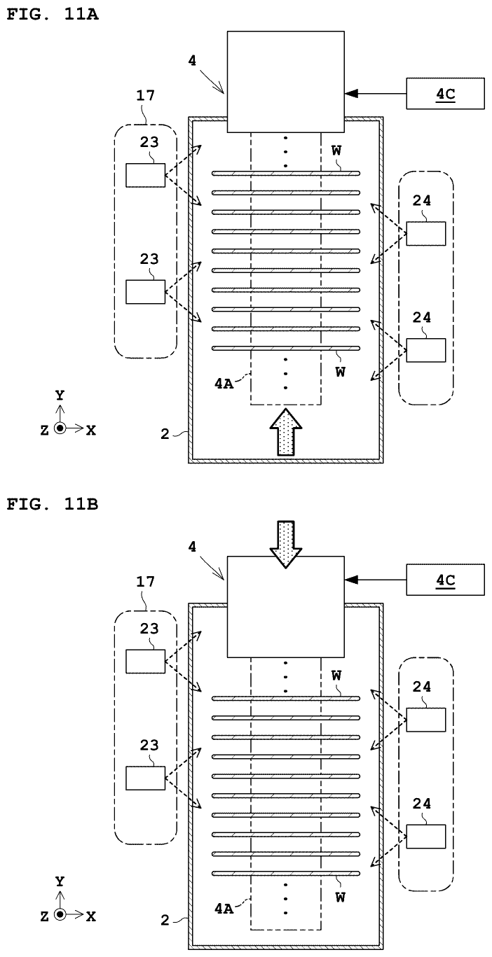

For example, to begin with, while the IPA is being sprayed from the mist nozzles 23, 24, the lifting unit 4B moves the holder 4A holding fifty substrates W up and down so that the fifty substrates W are passed between the nine mist nozzles 23 and the nine mist nozzles 24 (the operation of moving the substrates up and down). During this operation, the Y-direction actuator 4C swings the holder 4A in the Y direction, as shown in FIGS. 11A and 11B. The swinging width may be set to any width. Because the substrates W can be moved in the direction in which the substrates W are arranged (Y direction), the IPA is permitted to adhere directly to the substrates W more uniformly. The same applies to the case in which the water repellent is sprayed.

Furthermore, in this modification, the Y-direction actuator 4C is provided to the lifter 4, but it is possible for the Y-direction actuator 4C not to be provided in the lifter 4, and to have an independent configuration. The Y-direction actuator 4C may also configured to move the two nozzle rows 17 (mist nozzles 23, 24) in the Y direction, with respect to the holder 4A holding the fifty substrates W. The Y-direction actuator 4C corresponds to a relative actuator according to the present invention.

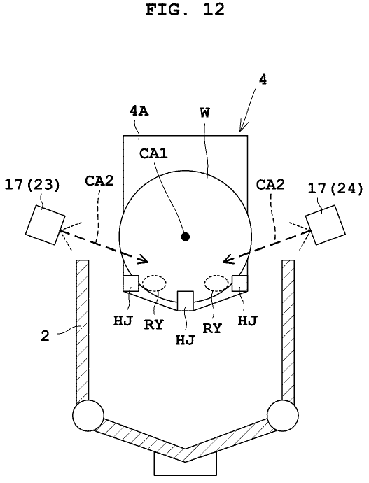

(4) In the embodiments and modifications described above, the mist nozzles 23 face the +X direction, and the mist nozzles 24 face the −X direction. That is, the mist nozzles 23, 24 faced each other in a horizontal direction. In this regard, the mist nozzles 23 may face the +X direction as well as the downward direction (−Z direction), and the mist nozzles 24 may face the −X direction as well as the downward direction (−Z direction). That is, the mist nozzles 23, 24 may be directed diagonally downwards. As a result, as shown in FIG. 12, in the holder 4A, the mist of the liquid is allowed to adhere directly to the surface of the substrates W on the rear sides of respective holding members HJ (e.g., areas RY) actually holding the substrates W in the vertical posture.

(5) In the embodiments and the modifications described above, the mist nozzles 23, 24 are configured to spray the IPA and the water repellent, selectively. In this regard, it is also possible to provide eighteen mist nozzles for the IPA and eighteen mist nozzles for the water repellent. Furthermore, the mist nozzles 23, 24 may be configured so as not to spray the IPA and the water repellent selectively. For example, the mist nozzles 23, 24 may spray a solvent, and another plurality of other nozzles may spray water repellent vapor. Furthermore, the mist nozzles 23, 24 may spray a water repellent, and another plurality of other nozzles may spray IPA vapor.

(6) In the embodiments and modifications described above, the substrate processing apparatus 1 is configured to spray the mist of the IPA (IPA mist) but not vapor of the IPA. In this regard, another nozzle (e.g., see the reference numeral NZ in FIG. 1) may be provided to supply the IPA vapor while the IPA mist is being sprayed. Because mist is relatively heavy, mist does not spread across the entire chamber 3. Therefore, with IPA vapor, the IPA is allowed to spread across the entire chamber 3, so that the inside of the chamber 3 can be cleaned thereby.

(7) In the embodiments and modifications described above, the liquid is a solvent or a water repellent. In this regard, the liquid may be pure water (e.g., DIW) or carbon dioxide water (CO₂ water), for example. For example, the mist nozzles 23, 24 may be configured to clean the fifty substrates W by spraying pure water to the fifty substrates W.

(8) In the embodiments and modifications described above, the substrate processing apparatus 1 includes two heaters HT1, HT2 as shown in FIG. 1. In this regard, the substrate processing apparatus 1 may not include the two heaters HT1, HT2. Furthermore, the substrate processing apparatus 1 may be provided with a heater on the common pipe 29, at a position between the junction pipe 31 and the branch pipe 29A shown in FIG. 2, instead of the two heaters HT1, HT2.

The present invention may be embodied in other specific forms without departing from the spirit or essential attributes thereof and, accordingly, reference should be made to the appended claims, rather than to the foregoing specification, as indicating the scope of the invention.

What is claimed is:

1. A substrate processing apparatus for processing a plurality of substrates, the substrate processing apparatus comprising:
a chamber configured to house a plurality of substrates in a vertical orientation, in a manner arranged linearly at a predetermined first interval in a horizontal direction;
a substrate holder provided inside the chamber and configured to hold the plurality of substrates;
a plurality of first nozzles provided inside the chamber and arranged at a predetermined second interval along an arrangement of the plurality of substrates;
a plurality of second nozzles provided inside the chamber and arranged at the second interval, along the arrangement of the plurality of substrates,
wherein the plurality of first nozzles are disposed on opposite sides of the plurality of second nozzles with respect to the plurality of substrates in plan view,
the plurality of first nozzles and the plurality of second nozzles are disposed in a manner facing the plurality of substrates in plan view,
the plurality of first nozzles are arranged in a manner offset from the plurality of respective second nozzles by a length corresponding to a half the second interval in a direction in which the plurality of substrates are arranged, and
each of the plurality of first nozzles and the plurality of second nozzles is configured to spray a liquid as at least one of mist and droplets.

2. The substrate processing apparatus according to claim 1, further comprising a control unit,
wherein the control unit is configured to cause the plurality of first nozzles and the plurality of second nozzles to alternately spray the liquid as the at least one of mist and droplets.

3. The substrate processing apparatus according to claim 1, wherein, in a condition in which each of the plurality of first nozzles and the plurality of second nozzles is disposed facing a central axis passing through the plurality of substrates, each of the plurality of first nozzles and the plurality of second nozzles is configured to spray the liquid as the at least one of mist and droplets so that the liquid is delivered directly across a range from a proximal end to a center of facing substrate.

4. The substrate processing apparatus according to claim 1, further comprising:
a lifting unit configured to move the substrate holder up and down; and
a control unit,
wherein the control unit is configured to cause the lifting unit to move the substrate holder up and down in such a manner that the plurality of substrates are passed between the plurality of first nozzles and the plurality of second nozzles, while the liquid is being sprayed from each of the plurality of first nozzles and the plurality of second nozzles.

5. The substrate processing apparatus according to claim 4, further comprising a relative actuator configured to move the substrate holder relatively with respect to the plurality of first nozzles and the plurality of second nozzles, along the direction in which the plurality of substrates are arranged.

6. The substrate processing apparatus according to claim 1, wherein the liquid is a solvent.

7. The substrate processing apparatus according to claim 1, wherein the liquid is a water repellent.

8. The substrate processing apparatus according to claim 1, further comprising:
a solvent supply unit capable of sending a solvent to each of the plurality of first nozzles and the plurality of second nozzles; and
a water repellent supply unit capable of sending a water repellent to each of the plurality of first nozzles and the plurality of second nozzles,
wherein when the solvent supply unit is sending the solvent while the water repellent supply unit is not sending the water repellent, each of the plurality of first nozzles and the plurality of second nozzles sprays the solvent as at least one of mist and droplets, and
when the water repellent supply unit is sending the water repellent while the solvent supply unit is not sending the solvent, each of the plurality of first nozzles and the plurality of second nozzles sprays the water repellent as at least one of mist and droplets.

9. The substrate processing apparatus according to claim 1, further comprising a processing tank provided inside the chamber and capable of storing a processing liquid,
wherein the plurality of first nozzles and the plurality of second nozzles are disposed at positions higher than the processing tank.
